(19) United States
(12) Patent Application Publication
(10) Pub. No.: US 2024/0421088 A1
(43) Pub. Date: Dec. 19, 2024

(54) POWER DISTRIBUTION WITH BACKSIDE POWER PLANES

(71) Applicant: INTERNATIONAL BUSINESS MACHINES CORPORATION, ARMONK, NY (US)

(72) Inventors: Nicholas Anthony Lanzillo, Wynantskill, NY (US); Lawrence A. Clevenger, Saratoga Springs, NY (US); Ruilong Xie, Niskayuna, NY (US); Huai Huang, Clifton Park, NY (US); Hosadurga Shobha, Niskayuna, NY (US)

(21) Appl. No.: 18/335,172

(22) Filed: Jun. 15, 2023

(51) Int. Cl. H01L 23/528; H01L 21/8238; H01L 23/498; H01L 23/535

(52) U.S. Cl. CPC H01L 23/5286; H01L 21/823871; H01L 23/49827; H01L 23/535

(57) ABSTRACT

A microelectronic structure including a backside-power-distribution-network (BSDPN) connected to a backside of a device region. The BSPDN includes a plurality of first type power rails and a plurality of second type power rails located on the same level. A first power plane located on a level above the plurality of first type power rails and the plurality of second type power rails. The first power plane extends across the plurality of first type power rails and the plurality of second type power rails and the first power plane is connected to a plurality of first type power rails, but not connected to the plurality of second type power rails.

### BACKGROUND

The present invention generally relates to the field of microelectronics, and more particularly to formation of a backside power distribution network having a power plane.

Nanosheet is the lead device architecture in continuing CMOS scaling. However, nanosheet technology has shown issues when scaling down such that as the devices become smaller and closer together, they are interfering with each other. With the decrease in size and spacing providing power in a cost-effective manner is becoming more difficult.

### BRIEF SUMMARY

Additional aspects and/or advantages will be set forth in part in the description which follows and, in part, will be apparent from the description, or may be learned by practice of the invention.

A microelectronic structure including a backside-power-distribution-network (BSDPN) connected to a backside of a device region. The BSPDN includes a plurality of first type power rails and a plurality of second type power rails located on the same level. A first power plane located on a level above the plurality of first type power rails and the plurality of second type power rails. The first power plane extends across the plurality of first type power rails and the plurality of second type power rails and the first power plane is connected to a plurality of first type power rails, but not connected to the plurality of second type power rails.

A microelectronic device including a backside-power-distribution-network (BSDPN) connected to a backside of a device region. The BSPDN includes a plurality of first type power rails and a plurality of second type power rails located on the same level. A first power plane located on a level above the plurality of first type power rails and the plurality of second type power rails. The first power plane extends across the plurality of first type power rails and the plurality of second type power rails and the first power plane is connected to a plurality of first type power rails, but not connected to the plurality of second type power rails. A second power plane is located on a second level, and the second power plane is located on a different level than the first power plane. An insulator layer is located between the first power plane and the second power plane. A metal-insulator-metal (MIM) capacitor is formed from the arrangement of the first power plane, the insulator layer, and the second power plane.

A microelectronic device including a backside-power-distribution-network (BSDPN) connected to a backside of a device region. The BSPDN includes a plurality of first type power rails and a plurality of second type power rails located on the same level. A first power plane located on a level above the plurality of first type power rails and the plurality of second type power rails. The first power plane extends across the plurality of first type power rails and the plurality of second type power rails. The first power plane is connected to a plurality of first type power rails, but not connected to the plurality of second type power rails. A plurality of metal lines located on a second level, and the plurality of metal lines are located on a different level than the first power plane.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of backside power distribution network (BSPDN), in accordance with the embodiment of the present invention.

FIG. 2 illustrates a cross section X2 of the BSPDN through an area where the skip vias are not located, in accordance with the embodiment of the present invention.

FIG. 3 illustrates a cross section X1 of the BSPDN through an area where the skip vias are located, in accordance with the embodiment of the present invention.

FIG. 4 illustrates a cross section X1 of the BSPDN through an area where the skip vias are located, in accordance with the embodiment of the present invention.

FIG. 5 illustrates a cross section X1 of the BSPDN through an area where the skip vias are located, in accordance with the embodiment of the present invention.

FIG. 6 illustrates a cross section X1 of the BSPDN through an area where the skip vias are located, in accordance with the embodiment of the present invention.

FIG. 7 illustrates a cross section X2 of the BSPDN through an area where the skip vias are not located, in accordance with the embodiment of the present invention.

FIG. 8 illustrates a cross section X1 of the BSPDN through an area where the skip vias are located, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards a backside-power-distribution-network (BSPDN), where the BSPDN utilizes a backside power plane to help distribute power. The power plane is a single metal layer/plane that extends across multiple metal lines or power rails; thus the power plane is able to distribute power simultaneously to multiple power rails. The one or more backside power planes allows for a reduction in the manufacture cost, by reducing the number of lithography steps and by reducing the number of levels (e.g., different metal layers) that are needed to distribute power to the device connected to the BSPDN. Furthermore, the power plane allows for global power distribution throughout the power plane. A power plane further has a lower resistance than metal lines, thus improving power delivery.

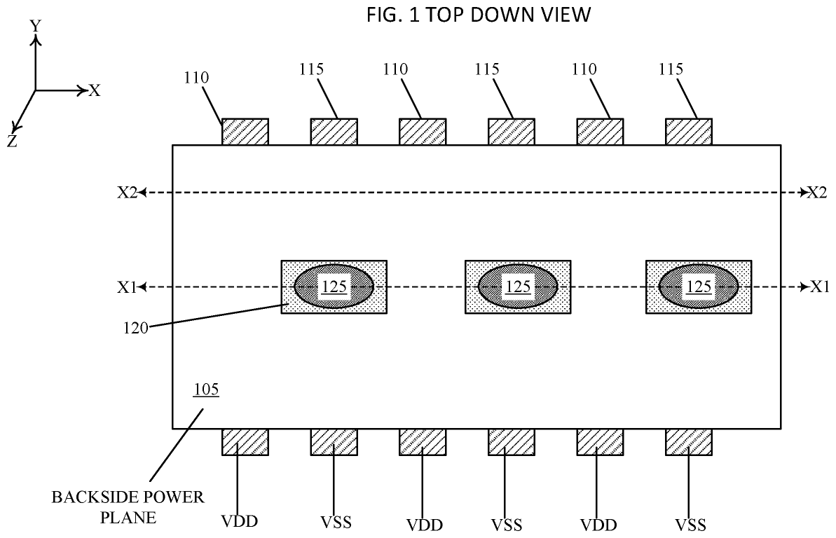

FIG. 1 illustrates a top-down view of a backside-power-distribution-network (BSPDN), in accordance with the embodiment of the present invention. The cross-section X1 extends horizontally through the BSPDN where at least one skip via passes/traverses through the power plane, where the cross-section is in direction of the X-axis (as indicated) perpendicular to the Y-axis. The cross-section X2 extends horizontally through the BSPDN where a skip via is not present, where the cross-section is in direction of the X-axis (as indicated) perpendicular to the Y-axis.

The power plane 105 is comprised of a conductive metal, where the power plane 105 extends across multiple power rails 110, 115. The first power rails 110 represent a power rail having a first type of potential, for example, the first power rails 110 can be, for example, VDD power rails. The second power rails 115 represent a power rail having a second type of potential, for example, the second power rails 115 can be, for example, VSS power rails. Power plane 105 extends in the X-axis direction and the Y-axis direction (to form a 2D shape profile from a top-down perspective) to cover a plurality of power rails 110, 115. If power plane 105 extends across the entire wafer which can lead to the wafer to warp, thus the power plane 105 does not extend across the entire wafer to avoid wafer warpage. Furthermore, by having the power plane 105 not extend across the entire wafer/chip allows for alignment markers (not shown) located at the edge of the wafer/chips to be exposed. These alignment markers allow for aligning the location/placement of the skip vias 125. Holes are formed through the entire depth of the power plane 105, where the holes are located above one type of power rails 110, 115. The holes in power plane 105 are lined with a dielectric liner 120. As seen in FIG. 1, the dielectric liner 120 is located around the perimeter of the hole, where the skip via 125 is located in the center of the hole. The dielectric liner 120 fully encloses and surrounds the sides of the skip via 125 as it passes through the power plane 105. Therefore, the dielectric liner 120 is sandwiched between the skip via 125 and the power plane 105. Dielectric liner 120 insulates the skip via 125 from shorting with the power plane 105 since the dielectric liner encloses the sides of the skip via 125 as it passes through the power plane 105.

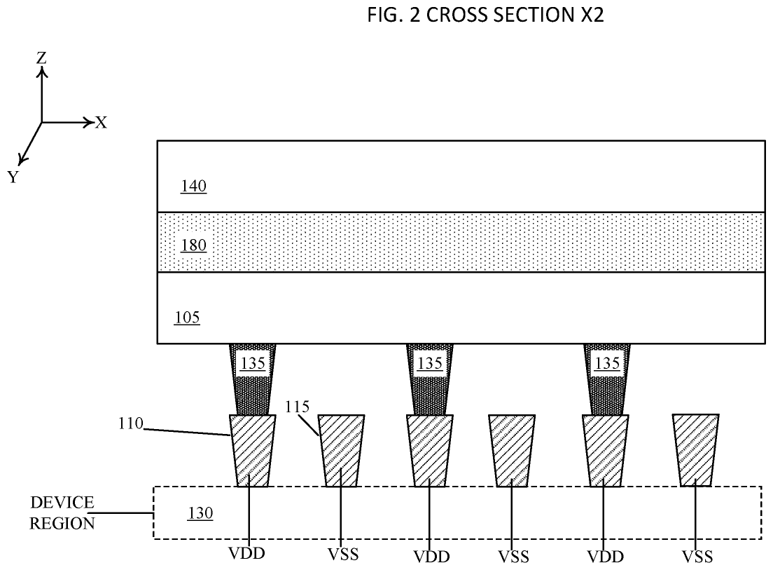

FIG. 2 illustrates a cross section X2 of the BSPDN through an area where the skip vias 125 are not located, in accordance with the embodiment of the present invention. The BSPDN is attached to the backside of an underlying device region 130. The underlying device region 130 can be any type of electronic device that needs a BSPDN, for example, the underlying device region 130 can be a logic device, integrated circuit, a passive device, or some other type of electronic device. The first type of power rails 110 and the second type of power rails 115 are located on the same level with the power plane 105 being located on a level above the power rails 110, 115. The power plane 105 can be attached/connected to the first type of power rail 110 by a connection via 135. FIG. 2 illustrates a metal plane 140 located above power plane 105. The metal plane 140 can be a second power plane, a metal line, or a combination thereof. The metal plane 140 and the power plane 105 have different power differential. The skip via 125 are connected to the metal plane 140 and connected to one of the power rails 110, 115 that are not connected to the power plane 105, thus the different power differentials can be provided to the underlying device region 130. The power plane 105 and the metal plane 140 are on different levels, where the power plane 105 is on a lower level that is closer to the device region than the level the metal plane 140 is located on. Furthermore, an insulator layer 180 can be located between the power plane 105 and the metal plane 140. The insulator layer 180 can be comprised of, for example, a high-k dielectric material. The configuration of the power plane 105, the insulator layer 180, and the metal plane 140 can form a metal-insulator-metal (MIM) capacitor. The MIM capacitor increases decoupling capacitance in the power grid of the BSPDN and reduces power supply noise. The insulator layer 180 can be comprised of a material that prevents or does form a MIM capacitor. Furthermore, the insulator layer 180 does not have to be present but a different material/layer or multiple layers can separate the power plane 105 and the metal plane 140.

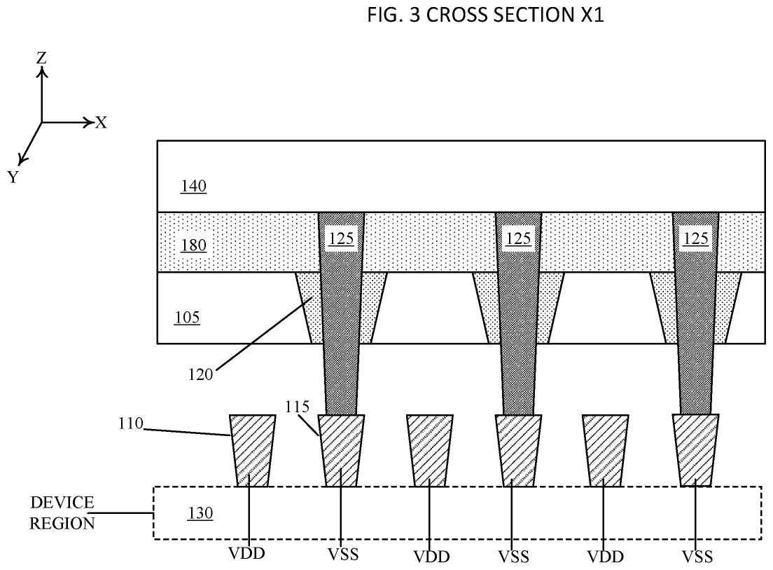

FIG. 3 illustrates a cross section X1 of the BSPDN through an area where the skip vias 125 are located, in accordance with the embodiment of the present invention. Skip via 125 are connected to the metal plane 140, where the metal plane 140 is a second power plane as illustrated in FIG. 2. The metal plane 140 (e.g., a second power plane) is simultaneously connected to a plurality of skip vias 125, to equally distribute the power through the metal plane 140 to the device region 130 via one of the power rails 110, 115. The skip vias 125 passes through the power plane 105 and is connected to the second type of power rails 115. The dielectric liner 120 is located between the sidewalls of the skip via 125 and the power plane 105 as the skip via 125 passes through the power plane 105. The dielectric liner 120 prevents the skip via 125 from shorting with the power plane 105.

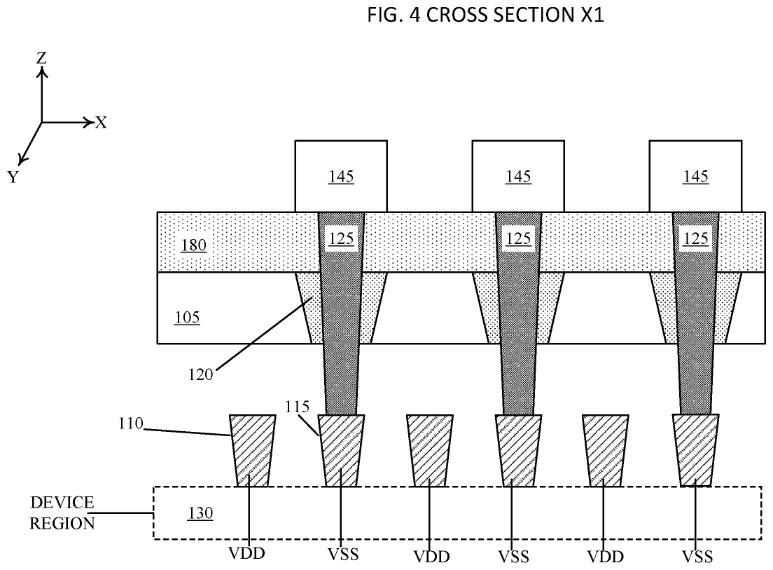

FIG. 4 illustrates a similar structure as illustrated in FIG. 3, but instead of the metal plane 140 being a second power plane, the metal plane 140 is replaced with a plurality of metal lines 145. The skip via 125 extends from the metal lines 145 to the second type of power rails 115. Metal lines 145 can have the same power potentials, different power potentials, same voltages, different voltages, same current, different currents, or any combination thereof, with respect to the other metal lines 145 or the power plane 105. Power plane 105 and the metal lines 145 are located on different levels such that the skip vias 125 passes through the power plane 105 to connect to the second type of power rails 115. As illustrated in FIGS. 1 and 4, the dielectric liner 120 completely surrounds the sides of the skip via 125 as it passes through power plane 105.

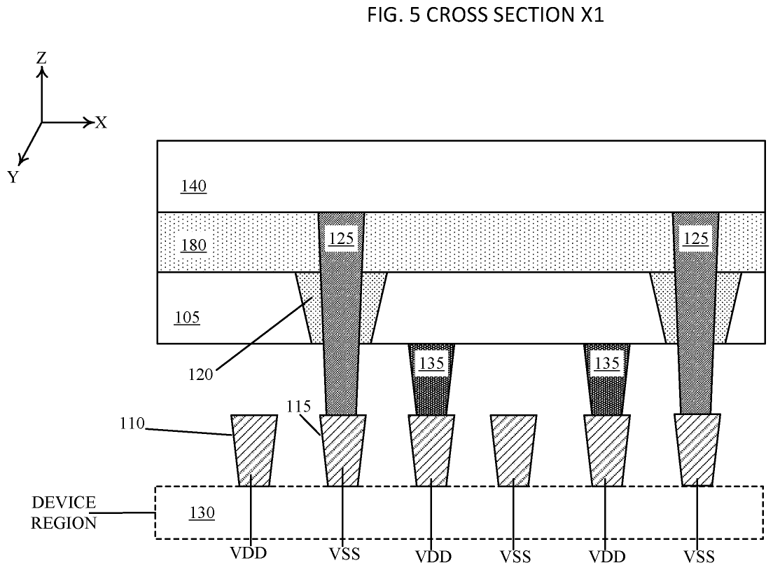

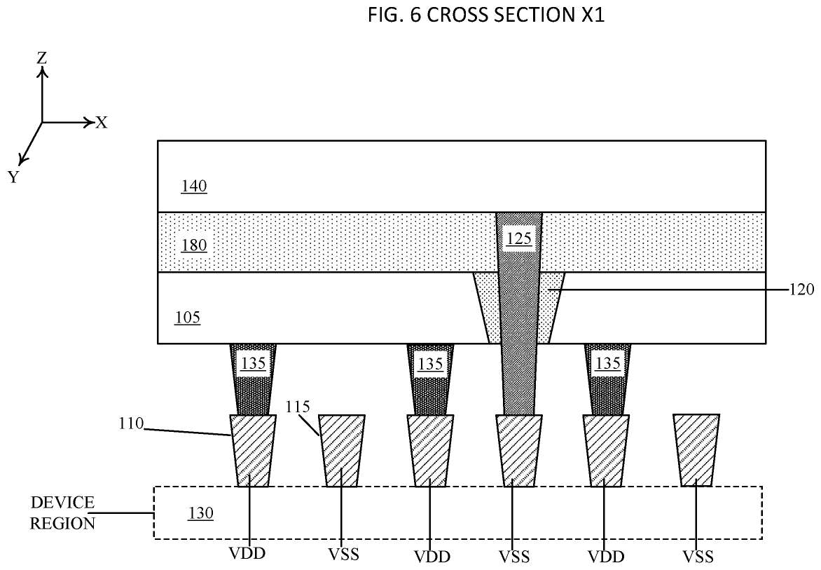

FIGS. 5 and 6 illustrate a similar structure as illustrated in FIG. 3 but illustrate a different configuration where the skip via 125 and the connection vias 135 are adjacent to each other. FIG. 5 shows the configuration where a plurality of connection vias 135 are located between two skips vias 125. The connection vias 135 connects the power plane 105 with the first type of power rails 110 and the skip vias 125 connects the metal plane 140 (or metal lines 145) to the second type of power rails 115. FIG. 6 illustrates the configuration of the skip via 125 being located between adjacent connection vias 135. FIG. 6 further illustrates that a plurality of skip vias 125 does not need to be located through the same horizontal cross-section of the BSPDN. The configuration/location of the connection vias 135 and the skip vias 125 can be varied to meet the needs of the underlying device region 130.

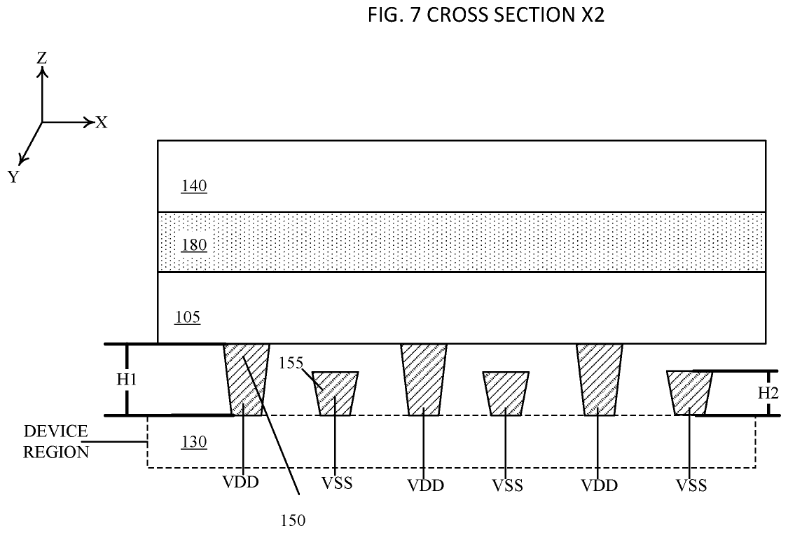

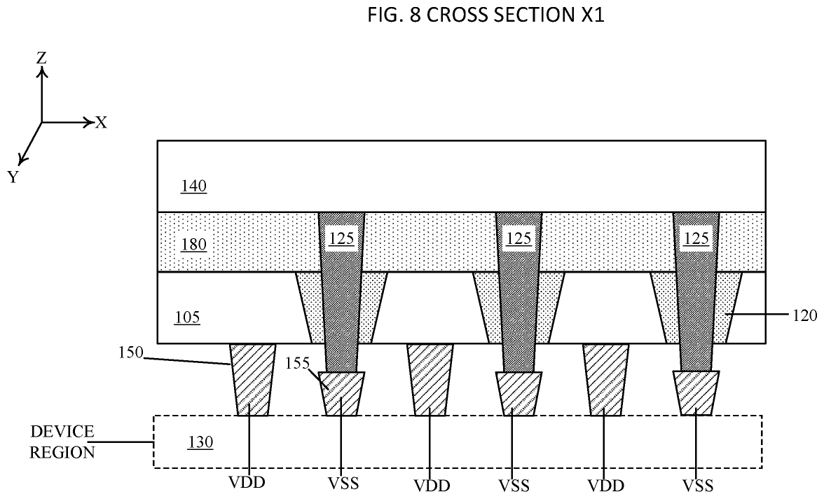

FIGS. 7 and 8 illustrate a configuration where the connection vias 135 are not present and power plane 105 is formed directly on a top surface of one type of power rail. The first type of power rails 150 and the second type of power rails 155 are located on the same level with the power plane 105 being located on a level above the power rails 150, 155. The power plane 105 is formed directly on the top surface of the first type of power rail 150. If the first type of power rails 150 and the second type of power rails 155 had the same dimensions, then the power plane 105 would short across the power rails 150, 155, since it would be in contact with both types. The shortage caused by the power plane 105 can be avoided by changing the dimensions of the second type of power rails 155. The first type of power rail 150 has a first height H1 and the second type of power rail 155 has a second height H2. The first height H1 is greater than the second height H2. The height difference between H1 and H2 is great enough to allow for the power plane 105 to rest on top of the first type of power rails 150 and prevents the power plane 105 from contacting the second type of power rails 155. This configuration simplifies the manufacturing process by removing the steps for formation of the contact vias 135 and increases the interface surface area interaction between the power plane 105 and the first type of power rails 150. Additionally, this configuration also reduces the overall height of the BSPDN since the contact vias 135 are no longer present. FIG. 8 illustrates the skip vias 125 passing through the power plane 105 and contacting the second type of power rails 155.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a backside-power-distribution-network (BSDPN) connected to a backside of a device region, wherein the BSPDN is comprised of:
a plurality of first type power rails and a plurality of second type power rails located on a same level; and
a first power plane located on a level above the plurality of first type power rails and the plurality of second type power rails, wherein the first power plane extends across the plurality of first type power rails and the plurality of second type power rails, wherein the first power plane is connected to the plurality of first type power rails, but not connected to the plurality of second type power rails.

2. The microelectronic structure of claim 1, further comprising:
a second power plane located on a second level, wherein the second power plane is located on a different level than the first power plane.

3. The microelectronic structure of claim 2, wherein the second power plane is connected to the plurality of second type of power rails but not connected to the plurality of first type of power rails.

4. The microelectronic structure of claim 3, further comprising:
a plurality of skip vias that connects the second power plane to the plurality of second type of power rails.

5. The microelectronic structure of claim 4, wherein each of the plurality of skip vias pass through the first power plane, wherein the first power plane surrounds the sidewalls of each of the plurality of skip vias.

6. The microelectronic structure of claim 5, further comprising:
a dielectric liner located adjacent to each of the plurality of skip vias.

7. The microelectronic structure of claim 6, wherein the dielectric liner is located directly adjacent to each of the plurality of skip vias where each of the plurality of skip vias passes through the first power plane.

8. The microelectronic structure of claim 7, wherein the dielectric liner is located between the sidewalls of each of the plurality of skip vias and the first power plane.

9. The microelectronic structure of claim 1, further comprising:
a plurality of connection vias connecting the first power plane to the plurality of first type of power rails.

10. The microelectronic structure of claim 1, wherein the first power plane is located directly on a top surface of the first type of power rails.

11. The microelectronic structure of claim 10, wherein the plurality of first type of power rails and the plurality of second type of power rails have different dimensions so that the plurality of second type of power rails does not contact the first power plane.

12. A microelectronic device comprising:
a backside-power-distribution-network (BSDPN) connected to a backside of a device region, wherein the BSPDN is comprised of:
a plurality of first type power rails and a plurality of second type power rails is located on a same level;
a first power plane located on a level above the plurality of first type power rails and the plurality of second type power rails, wherein the first power plane extends across the plurality of first type power rails and the plurality of second type power rails, wherein the first power plane is connected to the plurality of first type power rails, but not connected to the plurality of second type power rails;
a second power plane located on a second level, wherein the second power plane is located on a different level than the first power plane; and
an insulator layer located between the first power plane and the second power plane, wherein a metal-insulator-metal (MIM) capacitor is formed from the arrangement of the first power plane, the insulator layer, and the second power plane.

13. The microelectronic device of claim 12, wherein the second power plane is connected to the plurality of second type of power rails but not connected to the plurality of first type of power rails.

14. The microelectronic device of claim 13, further comprising:
a plurality of skip vias that connects the second power plane to the plurality of second type of power rails.

15. The microelectronic device of claim 14, wherein each of the plurality of skip vias pass through the first power plane, wherein the first power plane surrounds the sidewalls of each of the plurality of skip vias.

16. The microelectronic device of claim 15, further comprising:
a dielectric liner located adjacent to each of the plurality of skip vias.

17. The microelectronic device of claim 16, wherein the dielectric liner is located directly adjacent to each of the plurality of skip vias where each of the plurality of skip vias passes through the first power plane.

18. The microelectronic device of claim 17, wherein the dielectric liner is located between the sidewalls of each of the plurality of skip vias and the first power plane.

19. A microelectronic device comprising:
a backside-power-distribution-network (BSDPN) connected to a backside of a device region, wherein the BSPDN is comprised of:
a plurality of first type power rails and a plurality of second type power rails located on a same level;
a first power plane located on a level above the plurality of first type power rails and the plurality of second type power rails, wherein the first power plane extends across the plurality of first type power rails and the plurality of second type power rails, wherein the first power plane is connected to the plurality of first type power rails, but not connected to the plurality of second type power rails; and
a plurality of metal lines located on a second level, wherein the plurality of metal lines are located on a different level than the first power plane.

20. The microelectronic device of claim 19, wherein each of the plurality of metal lines are connected to one of the plurality of second type of power rails but not connected to the plurality of first type of power rails.
